(19) United States
(12) Patent Application Publication
(10) Pub. No.: US 2017/0062651 A1
(43) Pub. Date: Mar. 2, 2017

(54) Multicolor Electroluminescence from Intermediate Band Semiconductor Structures

(71) Applicants: W. Walukiewicz, Kensington, CA (US); N. Lopez, Madrid (ES); K.M. Yu, Lafayette, CA (US); T. Tanaka, Saga (JP)

(72) Inventors: W. Walukiewicz, Kensington, CA (US); N. Lopez, Madrid (ES); K.M. Yu, Lafayette, CA (US); T. Tanaka, Saga (JP)

(73) Assignee: The Regents of the University of California, Oakland, CA (US)

(21) Appl. No.: 15/174,604

(22) Filed: Jun. 6, 2016

Related U.S. Application Data
(60) Provisional application No. 62/211,584, filed on Aug. 28, 2015.

(51) Int. Cl. H01L 33/06; H01L 33/32; H01L 33/00; H01L 33/14

(52) U.S. Cl. CPC H01L 33/06; H01L 33/145; H01L 33/32; H01L 33/0075

(57) ABSTRACT

In various embodiments of the invention we have used GaNAs alloy with few percent of nitrogen as an active component of a device that simultaneously emits light of two different photon energies. The electroluminescence is produced by applying an electric field to an intermediate band solar cell device with electrically blocked intermediate band.

### CROSS REFERENCE TO RELATED APPLICATIONS

This U.S. Utility Application claims priority to U.S. Provisional Application Ser. No. 62/211,584 filed Aug. 28, 2015, which application is incorporated herein by reference as if fully set forth in their entirety.

### STATEMENT OF GOVERNMENTAL SUPPORT

The invention described and claimed herein was made in part utilizing funds supplied by the U.S. Department of Energy under Contract No. DE-ACO2-05CH11231 between the U.S. Department of Energy and the Regents of the University of California for the management and operation of the Lawrence Berkeley National Laboratory. The government has certain rights in this invention.

### BACKGROUND OF THE INVENTION

Field of the Invention

The present invention relates to the field of semiconductor emitters and detectors.

Related Art

The concept of multiband or intermediate solar cell (IBSC) has been proposed more than 50 years ago. There have been numerous attempts to find a material system that could satisfy the stringent requirements for the cell operation. The current status of the field has been recently reviewed by Okada, et. al. The first fully operational IBSC has been practically realized using GaNAs, a dilute nitride alloy belonging to the class of highly mismatched alloys (HMAs). The energy band structure of HMAs is determined by the interaction between localized states of the minority component (N) and extended conduction band states of the matrix (GaAs). This initial progress was further advanced in studies of IBSCs with GaInNAsSb and ZnOTe HMA absorbers.

A critical issue for the HMA based IBSCs is the strength of three optical transitions coupling the valence, intermediate and the conduction band. Although the contribution of a sequential absorption of two photons on the IBSC photocurrent has been recently observed there has been no direct observation of the optical transitions between the intermediate and upper conduction band.

In addition, devices emitting simultaneously at different photon energies are of great interest for high intensity color displays. Currently multicolor effects are achieved by using separate light emitting diodes (LEDs). The white color is also produced using emission from a fluorescent phosphorus excited by a UV LED. Currently dominant liquid crystal displays (LCD) technology based on backlight illumination does not provide high enough brightness to operate under daylight conditions. Several large companies work on light emitting diode (LED) or laser diode based displays. The main obstacle hampering the progress is a variation of the efficiency of these solid state emitters at different photon energies. A multicolor LED could be a breakthrough technology for the flat panel display industry.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1a and FIG. 1b illustrate a band diagram of the intermediate band solar cell structures. FIG. 1a, a blocked intermediate band (BIB) structure with the intermediate band isolated from contacts and two, front and back side, depletion regions. FIG. 1b, a reference unblocked intermediate band (UIB) solar cell structure with the intermediate band electrically connected to the back contact and a single, front side, depletion region.

FIG. 2 illustrates spectral dependence of the electroluminescence. Low temperature electroluminescence in blocked and unblocked intermediate band solar cell structures for forward and reverse bias conditions. A solid black line and dash black line correspond to forward and reverse bias electroluminescence from BIB structure respectively. A dotted black line represents forward bias electroluminescence from the UIB structure.

FIG. 3a and FIG. 3b illustrate a schematic illustration of the electroluminescence emission mechanism in the BIB structure. FIG. 3a, under forward and FIG. 3b reverse bias conditions.

FIG. 4a and FIG. 4b illustrate a temperature dependence of the electroluminescence spectra. FIG. 4a, for the BIB device 1 and FIG. 4b. for the BIB device 2. Different lines denote spectra measured at different temperatures.

FIG. 5a and FIG. 5b illustrate a temperature dependence of the electroluminescence energy peaks (E_{H} and E_{L}). Solid circles and squares represent experimental values for E_{H} and E_{L} respectively. The lines represent a theoretical fit using BAC model FIG. 5a for BIB device 1 and FIG. 5b for BIB device 2.

FIG. 6 illustrates a blocked intermediate band device design and the electronic band structure

FIG. 7a and FIG. 7b illustrate a schematic illustration of the EL generation under forward FIG. 7a and reverse FIG. 7b bias conditions in a blocked impurity band intermediate band solar cell structure.

FIG. 8 illustrates a low temperature electroluminescence in blocked and unblocked intermediate band solar cell structures for the forward and reverse bias conditions.

FIG. 9 illustrates schematics of an integrated double LED multicolor device with forward and reverse biased parts.

### DETAILED DESCRIPTION

In the discussions that follow, various process steps may or may not be described using certain types of manufacturing equipment, along with certain process parameters. It is to be appreciated that other types of equipment can be used, with different process parameters employed, and that some of the steps may be performed in other manufacturing equipment without departing from the scope of this invention. Furthermore, different process parameters or manufacturing equipment could be substituted for those described herein without departing from the scope of the invention.

These and other details and advantages of the present invention will become more fully apparent from the following description taken in conjunction with the accompanying drawings.

Various embodiments of the invention demonstrate that a unique distribution of the electric field in an IBSC allows observation of the two reverse-bias electroluminescence bands originating from the transitions between the intermediate and the conduction and the valence bands. The origin of these optical transitions is confirmed by the temperature dependence of the emitted photon energies deduced from the band anticrossing (BAC) model of the electronic band structure of GaNAs.

### Methods and Experimental Results

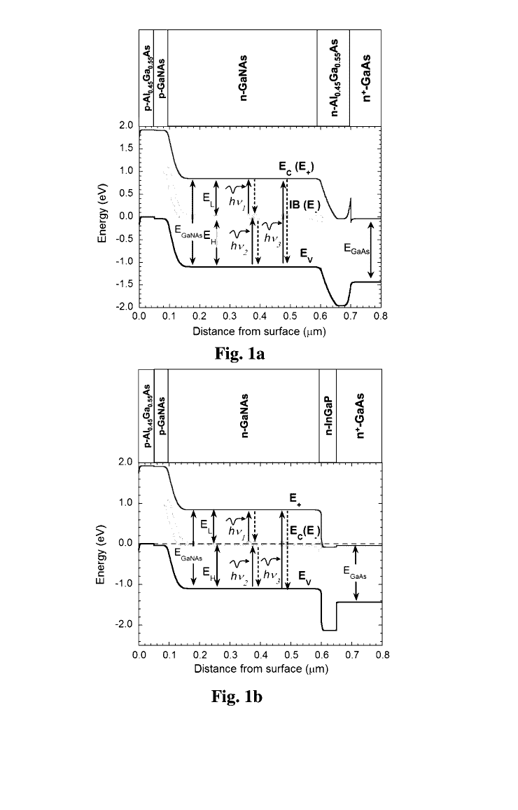

The IBSC device structures shown in FIG. 1a and FIG. 1b were grown using metal organic chemical vapor deposition (MOCVD). Two types of structures were grown. In the Blocked Intermediate Band (BIB) structure shown in FIG. 1 (a) the intermediate band is electrically isolated from the contacts whereas in the Unblocked Intermediate Band (UIB) structure, shown in FIG. 1 (b) the intermediate band is connected to the back side contact. As has been shown previously the BIB structure operates as an IBSC whereas the UIB structure works as a PV device with the energy band gap given by energy difference between intermediate and the valence band. Two BIB structures have been grown with different N concentrations. Structures with 3.1% and 3.8% N content are labeled as devices “1” and “2”, respectively.

The electroluminescence (EL) measurements were performed in the temperature range from 20 to 300 K. An alternating electrical current was applied to the devices placed in a liquid He cryostat. The emitted light passes through a monochromator and was detected by a germanium (Ge) detector using a lock-in amplifier.

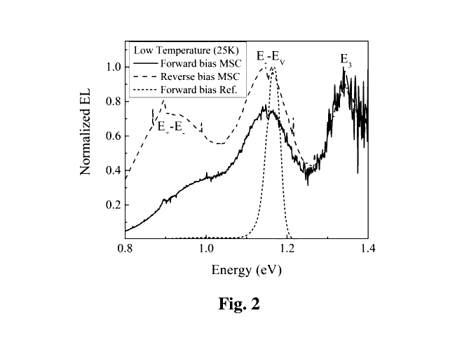

Electroluminescence spectra of both UIB, and BIB structures under forward bias are shown in FIG. 2. The UIB structure shows a single peak, at about 1.15 eV corresponding to the transition from the IB(E₋) to the valence band (E_{V}) (E_{H} in FIG. 1). This is consistent with the energy band diagram shown in FIG. 1 (b) where only one depletion region in the top part of the device is present. A forward bias produces occupation inversion resulting in the optical transition between the E₋ and the E_{V}.

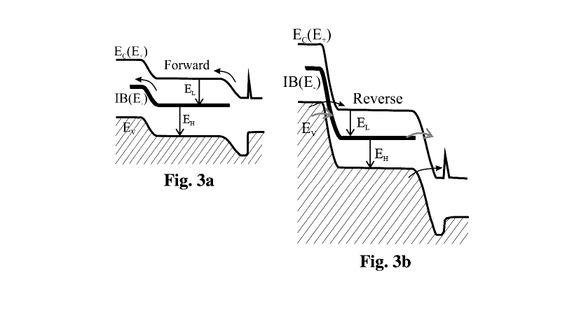

A more complex EL spectrum is observed in the BIB structure. It consists of two broad low energy peaks and a higher energy emission (E₃) close to the band gap of GaAs. The EL peak denoted E_{H} coincides with the emission peak found in UIB structure and can be attributed to the transitions from E₋ to E_{V} whereas the weak, low energy emission denoted E_{L} appears to be close to the energy separation between the E₊ and E₋ bands. This is a significant result as it appears to be the first direct observation of optical transitions between those two bands. The observation of these two transitions is the reflection of the fact that there are two depletion regions in the BIB device; one in the front part (close to the surface) and the other one in the back of the structure (close to the GaAs substrate). The applied voltage is distributed among those two regions. This is illustrated in the schematic band diagram of the BIB structure under forward bias shown in FIG. 3 (a). At the back side depletion region electrons that are injected from the substrate to the upper conduction band E₊ recombine radiative with holes in the partially occupied intermediate band, giving rise to a low energy emission (E_{L}). On the other hand, the higher energy emission (E_{H}) originates from the front side depletion region where electrons injected to the p-type region of the IB recombine with the holes in the valence band.

To further investigate these transitions we have measured the EL spectra under reverse bias conditions. No reverse-bias EL was found in the UIB structure confirming that the structure is equivalent to a single p-n junction. However, as is seen in FIG. 2, a well resolved two band EL spectrum is found in the BIB structure. Most notably a very strong low energy emission, E_{L}, with the peak energy at about 0.9 eV is clearly observed under the reverse bias conditions.

### DISCUSSION

This unusual result can be understood only assuming that the partially occupied IB (E₋) band is electrically isolated from the contacts in the BIB structure. When a reverse bias is applied to the BIB structure the total potential drop is distributed between the front side and the back side depletion regions. The mechanism of the two photon EL generation is schematically shown in FIG. 3 (b). At the front side depletion region a high enough reverse bias voltage can shift the valence band up and inject electrons from the valence band to the intermediate band and the conduction band, Ec (E₊). At the back side depletion region the reverse bias shifts down the conduction band of the GaAs substrate and injects holes into the intermediate band and the valence band. As a result an occupation inversion, with electrons in the E₊, holes in the E_{V} and electrons and holes in the IB is established in the middle of the BIB structure. These result in emissions associated with optical transitions between E_{C} and IB (E_{L}) as well as between IB and E_{V} (E_{H}).

Although both E_{L} and E_{H} emissions are observed for the forward and reverse bias conditions there is an important difference in the relative intensity of those two emissions under different bias conditions. Thus as is seen in FIG. 2, the E_{L} emission is much stronger under reverse bias. This is consistent with the schematic picture illustrating the origin of the E_{L} and E_{H} shown in FIG. 3a and FIG. 3b. Under forward bias the strong E_{H} emission originates from the front part of the structure whereas a weak E_{L} emission is mostly generated on the back side. In contrast under reverse bias the much stronger E_{L} emission is generated in the front side depletion region.

In principle, as is evident from FIG. 3 (b), for the reverse bias it should be possible to observe an even higher energy emission originating from radiative recombination of electrons injected to the E_{C} at the front side and holes injected to the E_{V} in the back side depletion region. However, this is unlikely as it would require long electron and/or hole diffusion lengths to diffuse across the 0.5 μm thick absorber layer. However, a modified structure with thinner mid-part absorber layer could possibly be used to observe all three optical transitions.

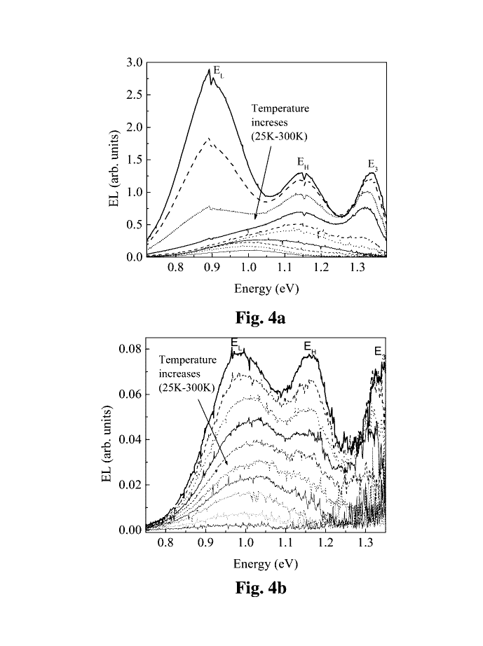

A possible concern is that the EL emission may be defect related i.e. originate from a transition between a localized defect state and the E_{V}, or E₋ band. To address this concern we have measured temperature dependence of the emission bands. FIG. 4a and FIG. 4b shows evolution of the emission bands energy as a function of temperature in both BIB structures. Although the two separate peaks could be resolved only for temperatures lower than ˜150 K it is clearly seen that the E_{L} band shifts to higher and the E_{H} band to lower energy with increasing temperature.

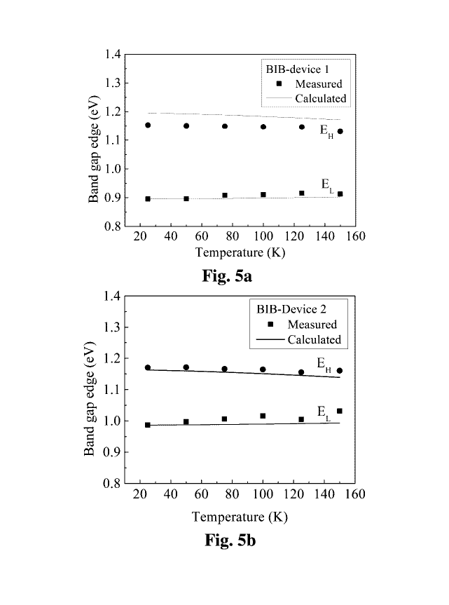

The energies of the E_{L} and E_{H} emission maxima were determined by fitting the spectra in FIG. 4a and FIG. 4b with Gaussian curves. The results are shown FIG. 5. In both devices the temperature coefficients for the E_{L} peak are positive and equal to +2.9×10⁻⁴ eV/K for device 1 and +1.7×10⁻⁴ eV/K for device 2 whereas the temperature coefficient for the maximum energy of the E_{H} peak are negative and equal to −1.1×10⁻⁴ eV/K for device 1 and −1.5×10⁻⁴ eV/K for device 2.

The unusual positive temperature coefficient for the E_{L} emission peak can be well understood assuming that emission originates from the transition between E₊ and E₋ bands.

The energies of the E₊ and E₋ sub-band edges are given by the BAC model in equation (1):

$${E}_{\pm } = \frac{( {E}_{N} + {E}_{M} ( T ) ) \pm {[ {( {E}_{N} - {E}_{M} ( T ) )}^{2} + 4 {C}_{NM}^{2} x ]}^{\frac{1}{2}}}{2} \qquad ( 1 )$$

Where E_{N} is the energy of the localized nitrogen level E_{M} is the conduction band edge of the GaAs matrix and C_{NM}=2.7 eV is the coupling constant. With the vacuum level as reference energy it can be assumed that the energy of the highly localized N level does not depend on temperature. Therefore the temperature dependence for the E₊ to E₋ transitions is given by (equation 2),

$$\frac{d ( {E}_{+} - {E}_{-} )}{d T} = \frac{( {E}_{M} ( T ) - {E}_{N} ) \frac{d {E}_{M} ( T )}{d T}}{\sqrt{{( {E}_{N} - {E}_{M} )}^{2} + 4 {C}_{NM}^{2} x}} \qquad ( 2 )$$

The temperature coefficient is positive as the terms dE_{M}/dT and (E_{M}−E_{N}) are negative. This accounts for the observed increase of the EL emission peak energy with increasing temperature. Such uncommon temperature behavior can be attributed to the fact that for E_{N} located above E_{M} the E₊−E₋ energy difference is controlled by the BAC interaction rather than the shift of E_{M}. The positive temperature coefficient excludes a possibility that the E_{L} peak could originate from transitions between a deep level and either the E₋ or the E_{V} bands since in both cases the transition energy is expected to decrease with increasing temperature because of the upward shift of the E_{V} and downward shift of the E₋ on the absolute scale. Also, the negative temperature coefficient for the E_{H} peak is consistent with transitions between E₋ and the valence band edge.

The observed two color EL is an unusual feature specific to the TB structure. This demonstrates that such structures could be used as multicolor emitters. Also, in addition the two observed emission bands a larger energy emission originating from recombination of the electrons injected into the E_{C} (E₊) at the front junction and holes injected into the E_{V} at the back junction should be also possible. This, however, would require a thinner absorber layer that separates the front and back junction.

We have provided the first experimental evidence for direct optical coupling between the intermediate band and the charge conducting bands in an intermediate band solar cell structure. Two electroluminescence emission peaks are observed, in reverse and forward bias, in the BIB structure due to the presence of a front and back depletion region in this structure. The emission bands show characteristic temperature dependence that confirms the role of band anticrossing in the formation of the intermediate band in dilute GaNAs. The results demonstrate that properly modified IBSC-like structures could be used as multicolor light emitters

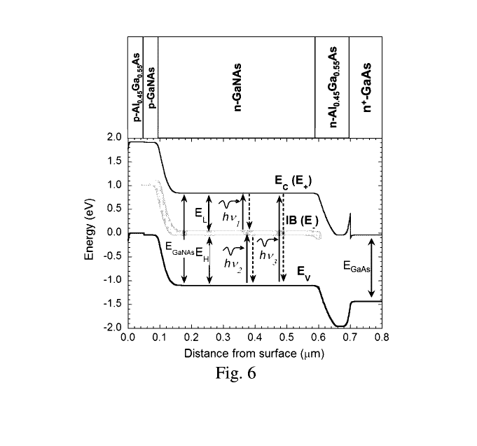

In various embodiments of the invention we have used GaNAs alloy with few percent of nitrogen as an active component of a device that simultaneously emits light of two different photon energies. The electroluminescence is produced by applying an electric field to an intermediate band solar cell device with electrically blocked intermediate band. The schematics of the device are shown in FIG. 6.

Unlike standard one color light emitters that operate only under forward bias conditions, the two color LED emits light when biased in either forward or reverse direction. This is possible because of the specific distribution of the charge depletion regions in the device structure with partially occupied blocked intermediate band.

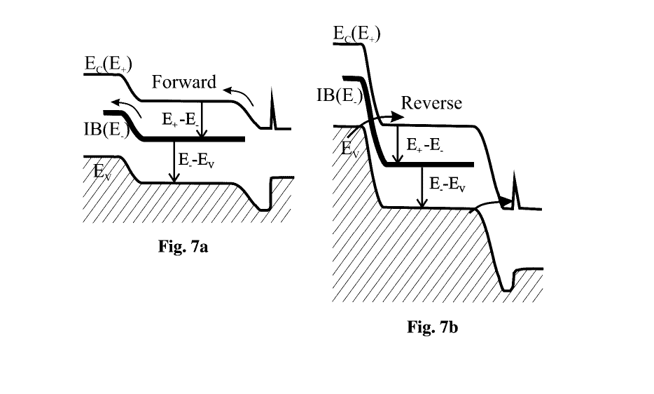

As is shown in FIG. 7a and FIG. 7b applying an electric field in either forward or reverse direction injects electrons to the conduction band and holes to the valence band. Since the intermediate band is partially occupied i.e. has both electrons and holes, the electrons injected to the conduction band recombine with holes in the intermediate band to emit photons of lower energy, EL and the holes injected into the valence band recombine with the electros in the intermediate band emitting photons of higher energy EH.

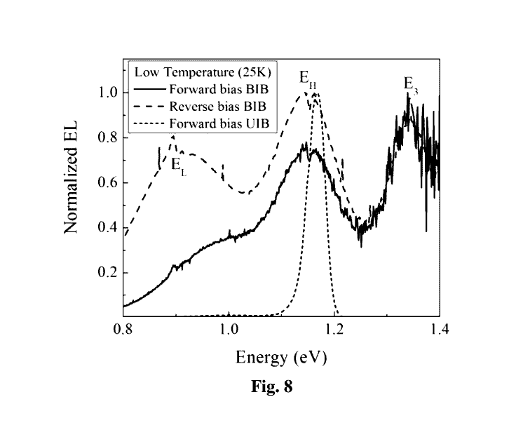

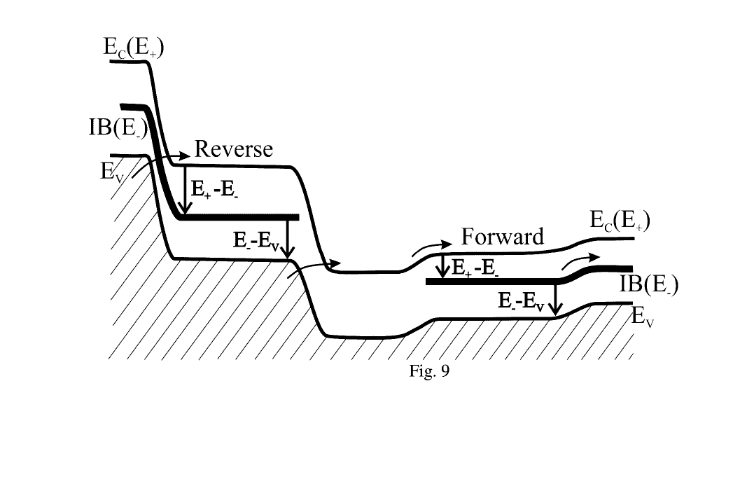

The emission spectrum measured on the device structure with the blocked intermediate band is shown in FIG. 8. The temperature dependence of the energies of two electroluminescence peaks is in agreement with transitions between conduction and intermediate band and between the intermediate and the valence band. The emission is relatively weak because the structures were grown for intermediate band solar cell applications that have relatively thick active GaNAs layer. It is expected that a properly designed and optimized structure should have much stronger emission intensities. In addition a third emission line at about 2 eV originating from the transitions between the conduction band and the valence band could be observed in a structure with thinner active layer. The important feature of the device is that it can operate under reverse and forward bias conditions. This offers a potential of combining, in a single device, two LED structures one biased in forward and the other in reverse direction. (see FIG. 9). Such device could be used to increase the intensity of the emission or to create emissions of different colors.

The presented two color device is possible because of the unique band structure of the highly mismatched GaNAs alloy in which quantum mechanical interaction of the nitrogen levels with the conduction band states of GaAs produces an intermediate band. The same concept can be extended to other highly mismatched alloys including group III-V dilute nitride alloys such as GaNAsP and group II-VI dilute oxide alloys such as ZnOTe, ZnOSe and ZnOS. The energy of the emitted photons depends on the type of the alloy and the alloy composition.

In standard LEDs emitted photons have a narrow energy range. Multicolor LEDs offer a potential for adjusting the color of the emitted light by mixing photons with different energies in a single device.

What is claimed is:

1. An intermediate band light emitting diode that simultaneously emits light of two different photon energies, comprising:
a GaAs substrate;
a semiconductor material formed on the GaAs substrate, wherein the semiconductor material comprises a III-V semiconductor alloy having intermediate energy bands, the semiconductor material comprising a p-type-GaNAs alloy and an n-type-GaNAs.

2. The intermediate band light emitting diode of claim 1, in which the substrate comprises n⁺-GaAs

3. The intermediate band light emitting diode of claim 2, further comprising a blocking layer between the substrate and the semiconductor material.

4. The intermediate band light emitting diode of claim 3, wherein the blocking layer comprises n-AlGaAs.

5. The intermediate band light emitting diode of claim 4, wherein the blocking layer comprises n-Al_{0.45}Ga_{0.55}As.

6. The intermediate band light emitting diode of claim 1, further comprising a second blocking layer formed on the p-GaNAs alloy.

7. The intermediate band light emitting diode of claim 6, wherein the second blocking layer comprises p-AlGaAs.

8. The intermediate band light emitting diode of claim 7, wherein the second blocking layer comprises p-Al_{0.45}Ga_{0.55}As.

9. A method of making an intermediate band light emitting diode that simultaneously emits light of two different photon energies, comprising:
forming a semiconductor material on a GaAs substrate, wherein forming the semiconductor material comprises forming a semiconductor material with an impurity to split a conduction band of the semiconductor material into two intermediate sub-bands, wherein forming the semiconductor material comprises forming a GaAsN alloy.

10. The method of claim 9, wherein the step of forming the semiconductor material comprises forming the GaAsN alloy on the GaAs substrate.

11. The method of claim 10, further comprising forming a blocking layer on the GaAs substrate before forming the semiconductor material on the GaAs substrate.

12. The method of claim 11, wherein the step of forming the semiconductor material comprises: forming a p-type GaAsN material; and forming a second n-type GaAsN material.

13. The method of claim 12, in which the substrate comprises n⁺-GaAs

14. The method of claim 13, further comprising forming the blocking layer between the GaAs substrate and the semiconductor material.

15. The method of claim 14, wherein the blocking layer comprises n-AlGaAs.

16. The method of claim 15, wherein the blocking layer comprises n-Al_{0.45}Ga_{0.55}As.

17. The method of claim 16, further comprising forming a second blocking layer on the p-GaNAs alloy.

18. The method of claim 17, wherein the second blocking layer comprises p-AlGaAs.

19. The method of claim 18, wherein the second blocking layer comprises p-Al_{0.45}Ga_{0.55}As.
